(19) United States
(12) Patent Application Publication
(10) Pub. No.: US 2009/0004813 A1
(43) Pub. Date: Jan. 1, 2009

(54) METHOD FOR FABRICATING SEMICONDUCTOR DEVICE WITH VERTICAL CHANNEL TRANSISTOR

(75) Inventor: Min-Suk LEE, Ichon-shi (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Ichon-shi (KR)

(21) Appl. No.: 11/951,957

(22) Filed: Dec. 6, 2007

(30) Foreign Application Priority Data
Jun. 26, 2007 (KR) 2007-0062808

(51) Int. Cl. H01L 21/76

(52) U.S. Cl. 438/421; 257/E21.54

(57) ABSTRACT

A method and system are provided for fabricating a semiconductor device that includes a vertical channel transistor. An area of a buried bit line is uniformly formed by an isolation trench. The width of the isolation trench is adjusted by controlling the thickness of spacers. Consequently, the area of the buried bit line is relatively large compared with that of a typical buried bit line. The resistance characteristics of the buried bit line are improved and stability and reliability of the semiconductor device are ensured.

### CROSS-REFERENCE TO RELATED APPLICATIONS

The present invention claims priority of Korean patent application number 2007-0062808, filed on Jun. 26, 2007, which is incorporated by reference in its entirety.

### BACKGROUND OF THE INVENTION

The present invention relates to a method for fabricating a semiconductor device, and more particularly, to a method for fabricating a semiconductor device having a vertical channel transistor.

As an integration degree of a semiconductor device is increased, a channel length of a transistor is gradually reduced. Such a reduction in the channel length of the transistor leads to a drain induced barrier lowering (DIBL) phenomenon, a hot carrier effect, and a short channel effect (SCE) such as a punch-through. In order to solve the above problems, various methods have been suggested. For instance, a method for reducing a depth of a junction area and a method for increasing a channel length by forming a recess in a channel area of a transistor have been suggested.

Since the integration degree of the semiconductor memory device, especially, the integration degree of a dynamic random access memory (DRAM), reaches a giga bit level, a transistor having a micro-size such as a transistor of a giga bit DRAM with a device area of 8F² (F: minimum feature size) or less, is required. Many giga bit DRAMs must have a device area of 4F². For this reason, a vertical channel transistor structure is suggested since a typical planar transistor structure, in which a gate electrode is formed over a substrate and junction regions are formed at both sides of the gate electrode, does not realize such a device region even if the channel length is scaled.

FIG. 1 is a perspective view of a semiconductor device having a typical vertical channel transistor.

Referring to FIG. 1, a plurality of pillars P are formed over a substrate 100. The pillars are made from a material identical to that of the substrate 100 and aligned in the first direction (X-X′) and the second direction (Y-Y′) crossing the first direction (X-X′). Generally, the pillars P are formed by etching the substrate 100 using hard mask patterns (not shown).

As shown, buried bit lines 101, which extend in the first direction while surrounding the pillars P, are formed in the substrate 100 between the pillars P aligned in the first direction. The buried bit lines 101 are separated from each other by an isolation trench T.

Surrounding gate electrodes (not shown) are provided at outer peripheral surfaces of the pillars P to surround the pillars P, and word lines 102 extend in the second direction while making an electric connection with the surrounding gate electrodes.

Storage electrodes 104 are formed over the pillars P. Contact plugs 103 can be interposed between the pillars P and the storage electrodes 104.

In a semiconductor device having the above structure as depicted in FIG. 1, channels are formed vertically to a surface of the substrate so that the channel length can be increased regardless of the surface area of the substrate. Thus, the SCE can be prevented. In addition, since the gate electrodes surround the outer peripheral surfaces of the pillars, a channel width of the transistor may be increased. As a result, the operational current of the transistor can be improved.

However, the device characteristics may be degraded due to a process fault that can occur when the buried bit lines 101 are formed as described above with respect to FIG. 1. This problem will be explained in more detail with reference to FIGS. 2A to 2E.

FIGS. 2A to 2E are cross-sectional views of a method for fabricating a semiconductor device having a typical vertical channel transistor. It should be noted that these sectional views are taken along the second direction (Y-Y′) shown in FIG. 1. In addition, these cross-sectional views are prepared to explain the problem occurring when forming the buried bit lines and detailed description of elements that do not relate to the above problem will be omitted.

Referring to FIG. 2A, a substrate structure includes a substrate 200 having a plurality of pillars P aligned in the first direction (X-X′) shown in FIG. 1 and the second direction crossing the first direction, hard mask patterns 201 provided on the pillars P and used to form the pillars P, and surrounding gate electrodes 202 that surround lower outer peripheral surfaces of the pillars P.

Bit line impurities are doped into the substrate 200 between the pillars P to form bit line impurities areas 203.

Referring to FIG. 2B, an insulation layer 204 is formed over the whole area of the substrate structure and then the insulation layer 204 is planarized.

Then, Referring to FIG. 2C, mask patterns 205, which have slits S for exposing the substrate 200 between the pillars P aligned in the first direction, are formed over the planarized insulation layer 204. Thus, the slits S of the mask patterns 205 extend in parallel to the first direction.

After that, referring to FIG. 2D, the insulation layer 204 exposed through the slits S is etched to expose the substrate 200. During the etching process, the mask patterns 205 are used as an etch barrier.

Referring to FIG. 2E, the exposed substrate 200 is etched by a predetermined depth, forming isolation trenches T in the form of slits.

As shown, the isolation trenches T are formed in the substrate 200 between the pillars P aligned in the first direction and extend in parallel to the first direction. The isolation trenches T extend downward beyond the bit line impurity areas 203, thereby defining buried bit lines 203A extending in the first direction while surrounding the pillars P.

Typically, subsequent processes, including a process for forming word lines which extend in the second direction while making an electric connection with the surrounding gate electrodes 202, a process for exposing the pillars P by removing the hard mask patterns 201, and a process for forming contact plugs and storage electrodes over the exposed pillars P, are sequentially performed.

However, when the mask patterns 205 are formed over the insulation layer 204, a width of the slit S cannot be sufficiently reduced due to an exposure limitation in a photolithography process. This may increase the resistances of the buried bit lines. That is, as the width of the slit S becomes enlarged, the width of the isolation trench T corresponding to the slit S is also enlarged and, as a result, an area for the buried bit lines 203A is reduced. Such reduced area for the buried bit lines contributes to an increase of resistance Rs of the buried bit lines 203A.

In addition, it is difficult to uniformly control an area and resistance of the buried bit lines 203A when the insulation layer 204 is etched by using the mask patterns 205 as an etching barrier. The exposed substrate 200 has an area that typically depends on the etching characteristics.

### SUMMARY OF THE INVENTION

Embodiments of the present invention are directed to a method for fabricating a semiconductor device that includes a vertical channel transistor where an area of a buried bit line is uniformly formed while the area of the buried bit line is increased compared with that of a typical buried bit line, thereby improving resistance characteristics of the buried bit line and ensuring stability and reliability when fabricating the semiconductor device.

In accordance with an aspect of the present invention, there is provided a method for fabricating a semiconductor device having a vertical channel transistor. The method includes forming a plurality of pillars over a substrate in which a hard mask pattern is formed over the pillars. The pillars are aligned in a first direction and a second direction crossing the first direction. The method further includes forming a bit line impurity area over the substrate between the pillars, forming an insulation layer over a whole area of the resultant structure including the pillars and the bit line impurity area, and forming a mask pattern over the insulation layer to expose the substrate between the pillars aligned in the first direction. Subsequently, the insulation layer is etched by using the mask pattern as an etching mask, wherein an opening for exposing the substrate and a resultant structure are formed. A spacer is formed at a sidewall of the opening such that a width of the substrate exposed through the opening is reduced. The exposed substrate is etched to have a width reduced by the spacer. The method further includes forming an isolation trench and defining a buried bit line extending in the first direction while surrounding the pillars.

### BRIEF DESCRIPTION OF THE DRAWINGS

FIG. 1 is a perspective view of a typical semiconductor device having a vertical channel transistor.

FIGS. 2A to 2E are cross-sectional views of a method for fabricating a typical semiconductor device having a vertical channel transistor.

FIGS. 3A to 3I are cross-sectional views of a method for fabricating a semiconductor device having a vertical channel transistor in accordance with an embodiment of the present invention.

### DESCRIPTION OF SPECIFIC EMBODIMENTS

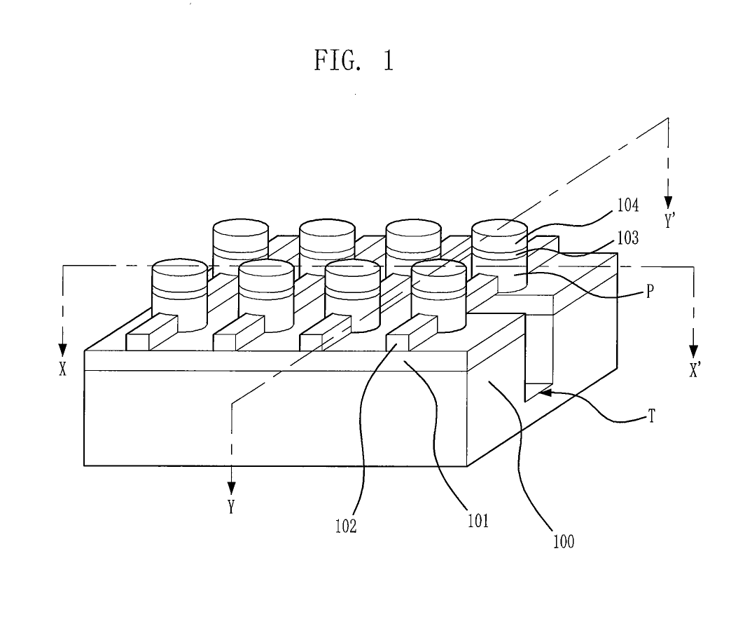

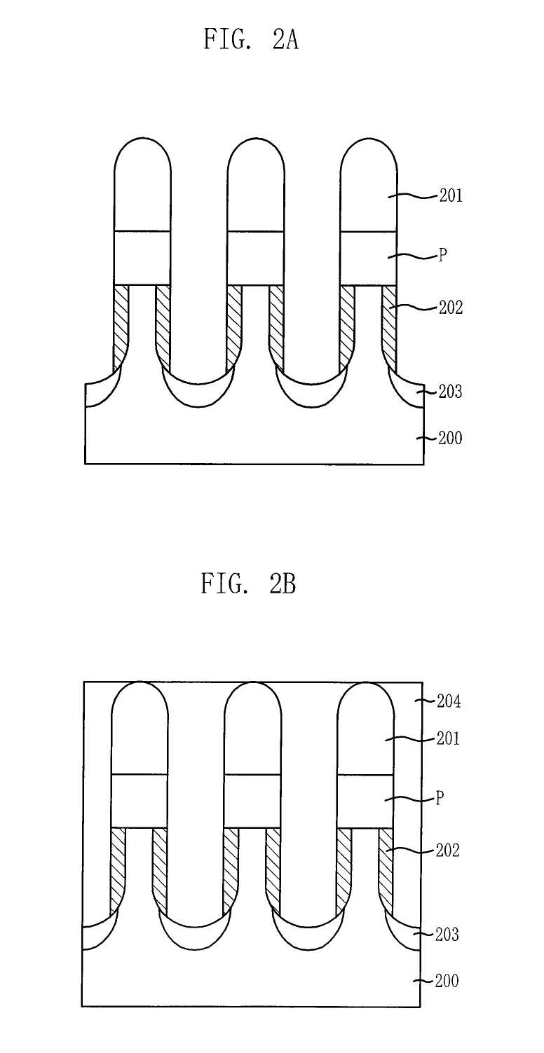

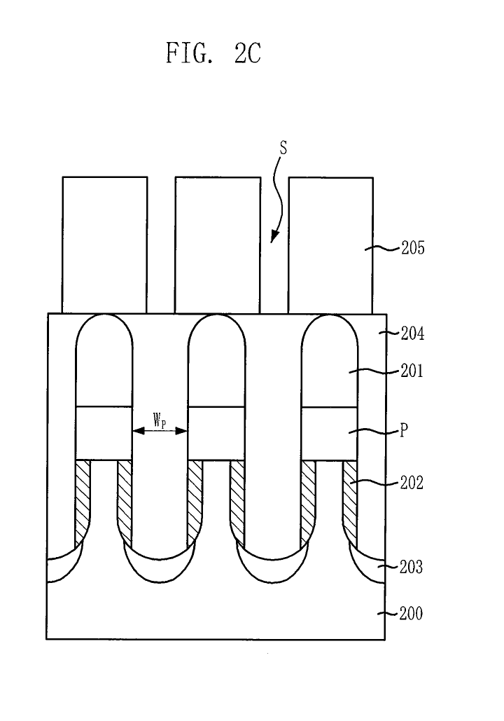

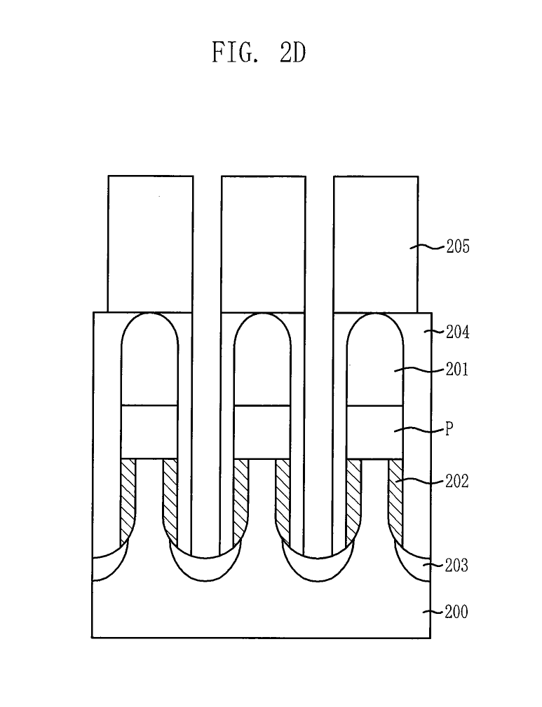

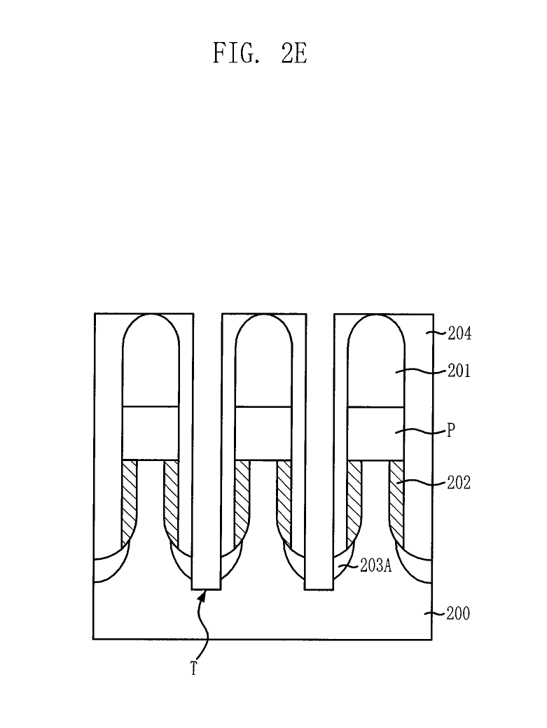

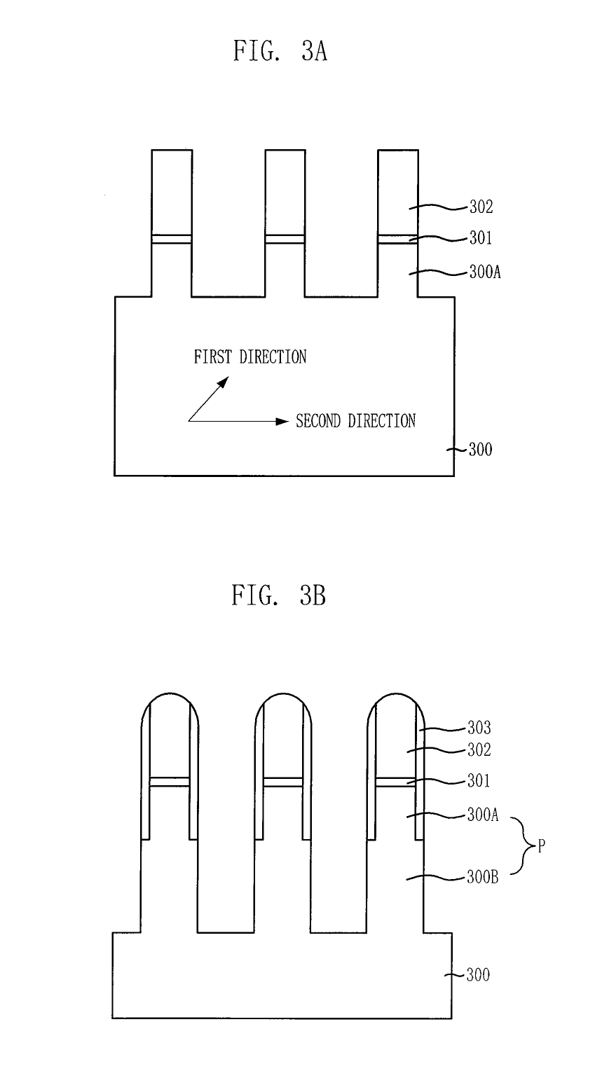

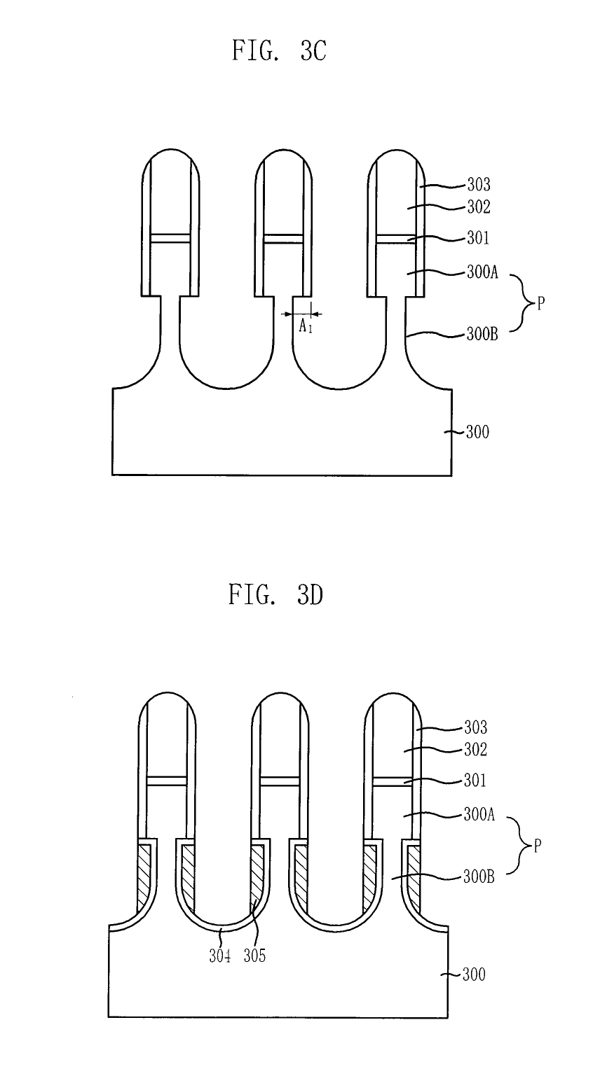

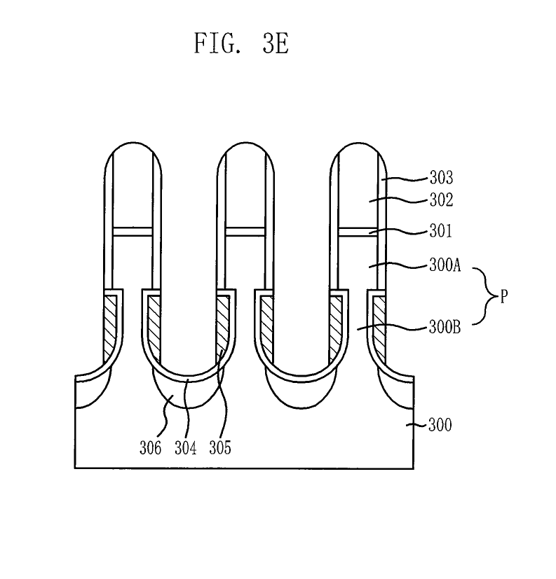

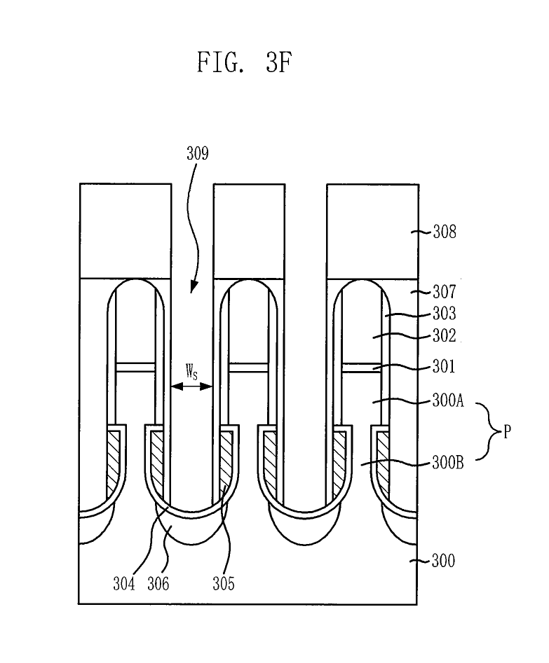

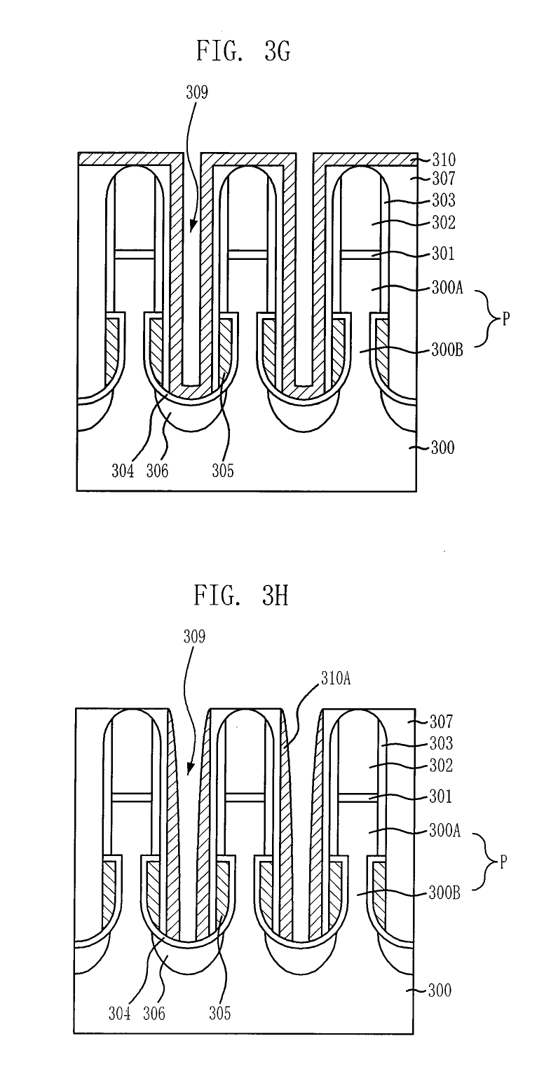

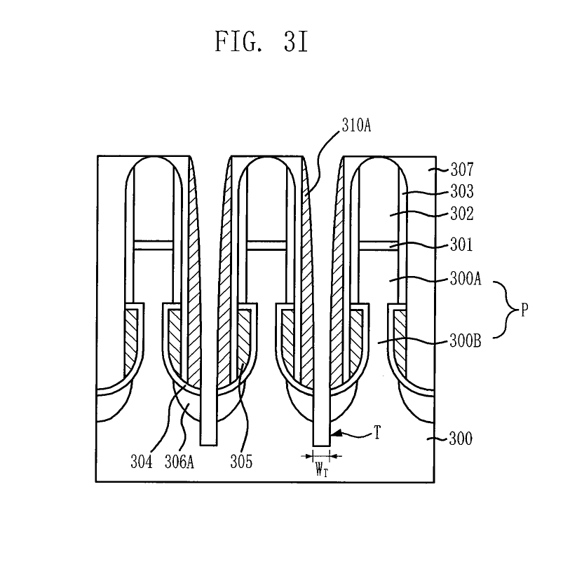

FIGS. 3A to 3I are cross-sectional views of a method for fabricating a semiconductor device having a vertical channel transistor in accordance with an embodiment of the present invention. It is to be noted that these cross-sectional views are taken along the second direction (Y-Y′) shown in FIG. 1.

Referring to FIG. 3A, a plurality of hard mask patterns 302 are formed over a substrate 300 in the first direction (X-X′) shown in FIG. 1 and the second direction crossing the first direction. Pad oxide layers 301 can be formed under the hard mask patterns 302.

The substrate 300 is etched by a predetermined depth using the hard mask patterns 302 as an etch mask, thereby forming pillar upper portions 300A.

A first spacer material layer is subsequently formed over the entire surface of a resultant structure. Referring to FIG. 3B, the first spacer material layer is etched back to form first spacers 303 at sidewalls of the hard mask patterns 302 and the pillar upper portions 300A.

The substrate 300 is then etched to a predetermined depth using the hard mask patterns 302 and the first spacers 303 as an etch mask, thereby forming pillar lower portions 300B, which are integrally formed with the pillar upper portions 300A.

As a result, pillars P including the pillar upper portions 300A and the pillar lower portions 300B are obtained as an active area. The pillars P are aligned in the first direction and the second direction crossing the first direction. It is noted that the hard mask patterns 302 may have rectangular shapes when viewed in a plan view. However, the pillars P have substantially cylindrical structures through the etching process, etc, as shown in FIG. 3B

Referring to FIG. 3C, sidewalls of the pillar lower portions 300B are isotropically etched such that the sidewalls of the pillar lower portions 300B can be recessed by a predetermined width A in accordance with an embodiment. In this embodiment, the hard mask pattern 302 and the first spacer 303 are used as an etch barrier. The predetermined width A of the recessed pillar lower portions 300B may correspond to a predetermined thickness of surrounding gate electrodes which are formed later through a subsequent process.

Referring to FIG. 3D, a gate insulation layer 304 is formed over the surface of the exposed substrate 300.

Subsequently, a conductive layer for a gate electrode is formed over the whole area of the resultant structure. The conductive layer is etched back until the gate insulation layer is exposed. As a result, the surrounding gate electrodes 305 are formed such that the surrounding gate electrodes 305 surround outer peripheral surfaces of the recessed pillar lower portions 300B.

Referring to FIG. 3E, bit line impurities are doped into the substrate 300 between the pillars P, thereby forming bit line impurity areas 306. N-type impurity may be used for the bit line impurity.

Referring to FIG. 3F, an insulation layer 307 is formed over the whole area of the resultant structure and then the insulation layer 307 is planarized.

Subsequently, mask patterns 308, which have slits for exposing the substrate between the pillars P aligned in the first direction, are formed over the planarized insulation layer 307. The slits of the mask patterns 308 extend in parallel to the first direction. In one embodiment, a width Ws of the slit is smaller than an interval between the pillars P aligned in the first direction. As will be well appreciated, the slit may still have a relatively large width within the exposure limitation level of the photolithography process so that the mask patterns 308 can be easily formed.

The insulation layer 307 exposed through the slits is etched by using the mask pattern 308 as an etching mask, thereby forming openings 309 in the form of slits for exposing the substrate 300. It is noted that a width of the exposed substrate may vary depending on the etching characteristics of the insulation layer 307. To solve this problem, processes as shown in FIGS. 3G and 3H are performed.

Referring to FIG. 3G, an insulation layer 310 for a second spacer is formed over the whole area of the resultant structure including the openings 309. The insulation layer 310 for the second spacer is shallowly formed with a thickness ranging from approximately 1 Å to approximately 999 Å. The insulation layer 310 for the second spacer is formed by using a material having superior step coverage characteristics and/or a method, for example, a chemical vapor deposition (CVD) or an atomic layer deposition (ALD), so that the insulation layer 310 formed over the bottom and sidewalls of the openings 309 has a uniform thickness.

Referring to FIG. 3H, the insulation layer 310 for the second spacer is subject to a spacer etch process such that second spacers 310A can be formed at sidewalls of the openings 309. Since a thickness of the second spacer 310A can be easily adjusted by controlling the etching degree, a width of the exposed substrate 300 can also be easily adjusted. In addition, the width of the exposed substrate 300 is smaller than a width Ws of the slit of the mask pattern 308 due to the second spacer 310A. As will be well appreciated, such a reduction in the width of the exposed substrate 300 should be limited to the extent that the buried bit lines can be separated from each other.

Referring to FIG. 3I, the exposed substrate 300 having the reduced width due to the second spacer 310A is etched to a predetermined depth so that isolation trenches T in the form of slits are formed in the substrate 300 between pillars P aligned in the first direction. The isolation trenches T extend in parallel to the first direction. A width W_{T} of the isolation trench T is also reduced in correspondence with the width of the exposed substrate 300, so the width W_{T} of the isolation trench T is smaller than the width Ws of the slit of the mask pattern 308 (FIG. 3H).

The isolation trenches T extend downward beyond the bit line impurity areas 306 (FIG. 3H), thereby defining buried bit lines 306A extending in the first direction while surrounding the pillars P. In one embodiment, the buried bit lines 306A are separated from each other by the isolation trenches T. The isolation trenches T are formed to have a depth ranging from approximately 100 Å to approximately 9,999 Å. When the substrate 300 is etched to form the isolation trenches T, gas having a higher etching selectivity relative to the insulation layer, e.g., chlorine (Cl₂), hydrogen bromide (HBr) or boron trichloride (BCl₃), is employed to prevent the second spacers 310A and/or the hard mask patterns 302 from being damaged.

As described above, the area of the buried bit line 306A is increased as the width W_{T} of the isolation trench T is reduced so that the resistance of the buried bit line 306A can be reduced.

As will be appreciated by one of ordinary skill in the art, various subsequent processes are sequentially performed after the above mentioned processes. For example, the subsequent processes include, but are not limited to, a process for forming word lines which extend in the second direction while making an electric connection with the surrounding gate electrodes 305, a process for exposing the pillars P by removing the hard mask patterns 302 and the pad oxide layers 301, and a process for forming contact plugs and storage electrodes over the exposed pillars P.

In one embodiment, width W_{T} of the isolation trench T is adjusted by controlling the thickness of the second spacer 303 without adjusting the slit width Ws of the mask pattern 308. The area of the buried bit line 306A defined by the isolation trench T can be increased and uniformly formed. Further, the process can be easily performed because the slit width Ws does not have to be reduced in order to prevent the process fault when the mask pattern 308 is formed.

As is apparent from the above described embodiments, the area of the buried bit line can be increased and uniformly formed as compared with that of a typical buried bit line. As a result, the resistance characteristics of the buried bit line can be improved and stability and reliability can be ensured when the semiconductor device is fabricated.

While the present invention has been described with respect to the specific embodiments, the above embodiments of the present invention are illustrative and not limitative. It will be apparent to those skilled in the art that various changes and modifications may be made without departing from the spirit and scope of the invention as defined in the following claims.

What is claimed is:

1. A method for fabricating a semiconductor device having a vertical channel transistor, the method comprising:
forming a plurality of pillars over a substrate, wherein a hard mask pattern is formed over the plurality of pillars and the plurality of pillars are aligned in a first direction and a second direction crossing the first direction;
forming a bit line impurity area over the substrate between the pillars;
forming an insulation layer over a whole area of a resultant structure, wherein the resultant structure includes the plurality of pillars and the bit line impurity area;
forming a mask pattern over the insulation layer to expose the substrate between the plurality of pillars aligned in the first direction;
etching the insulation layer using the mask pattern as an etch mask to form an opening for exposing the substrate;
forming a spacer at a sidewall of the opening to reduce a width of the substrate exposed through the opening; and
forming an isolation trench by etching the exposed substrate having a width reduced by the spacer.

2. The method of claim 1, further comprising planarizing the insulation layer.

3. The method of claim 1, wherein the mask pattern includes slits for exposing the substrate between the plurality of pillars aligned in the first direction.

4. The method of claim 3, wherein the slit has a width smaller than an interval between the pillars aligned in the first direction.

5. The method of claim 3, wherein the opening and the isolation trench form a slit.

6. The method of claim 1, wherein forming the spacer includes:
forming an insulation layer for the spacer over a whole area of the resultant structure including the opening; and
anisotropically etching the insulation layer to form the spacer.

7. The method of claim 6, wherein the insulation layer for the spacer has a thickness ranging form approximately 1 Å to approximately 999 Å.

8. The method of claim 6, wherein the insulation layer for the spacer has a uniform thickness over a whole area of the resultant structure.

9. The method of claim 1, wherein a width and a depth of the isolation trench are set within a predetermined range such that the buried bit lines are separated from each other.

10. The method of claim 1, wherein the depth of the isolation trench ranges from approximately 100 Å to approximately 9,999 Å.

11. The method of claim 1, wherein gas having a higher selectivity ratio to the spacer is employed when forming the isolation trench.

12. The method of claim 11, wherein the gas includes one selected from a group consisting of chlorine (Cl₂), hydrogen bromide (HBr), boron trichloride (BCl₃), and a combination thereof.

13. The method of claim 1, further comprising forming a surrounding gate electrode that surrounds a lower outer peripheral surface of each pillar.

14. The method of claim 13, wherein the lower outer peripheral surface of each pillar is recessed corresponding to a thickness of the surrounding gate electrode.

15. The method of claim 13, further comprising:
forming a word line to be electrically connected with the surrounding gate electrode, wherein the word line extends in the second direction;
exposing each pillar by removing the hard mask pattern formed over the pillar; and
forming a storage electrode over the exposed pillar.

16. The method of claim 1, wherein etching the exposed substrate having a width reduced by the spacer includes defining a buried bit line extending in the first direction, the buried bit line surrounding the pillars.
